(19) United States
(12) Patent Application Publication
(10) Pub. No.: US 2026/0235481 A1
(43) Pub. Date: Aug. 13, 2026

(54) PICKUP METHOD, TEST METHOD, PICKUP DEVICE, AND TEST APPARATUS

(71) Applicant: DISCO CORPORATION, Tokyo (JP)

(72) Inventor: Yuya Matsuoka, Tokyo (JP)

(21) Appl. No.: 19/445,092

(22) Filed: Jan. 9, 2026

(30) Foreign Application Priority Data
Feb. 13, 2025 (JP) 2025-021856

(51) Int. Cl. G01N 3/02; B25J 11/00; G01N 3/08

(52) U.S. Cl. CPC G01N 3/02; B25J 11/0095; G01N 3/08

(57) ABSTRACT

There is provided a pickup method including adjusting a relative position of an ejector mechanism and a chip in such a manner that a pin is positioned at a first position of the chip, applying a holding force to a holding surface of the ejector mechanism with a tip end portion of the pin being positioned in a retracted position and holding the other surface of a sheet on the holding surface, moving the tip end portion of the pin to the protrusion position, and pushing up the chip with the pin, thereby peeling off part of the chip from the sheet, adjusting the relative position between the ejector mechanism and the chip, in such a manner that the pin is positioned at a second position of the chip different from the first position, thereby enlarging a peel-off region, and picking up the chip.

### BACKGROUND OF THE INVENTION

### Field of the Invention

The present invention relates to a pickup method which picks up a chip fixed to one surface of a sheet therefrom, a test method which measures a load applied when the chip having been picked up is broken, a pickup device which picks up the chip fixed to the one surface of the sheet therefrom, and a test apparatus which measures the load applied when the chip having been picked up is broken.

### Description of the Related Art

There has been known a pickup device which picks up each of a plurality of rectangular chips fixed on the sheet (see, for example, Japanese Patent Laid-Open No. 2022-021643). In order to pick up one chip in this pickup device, a lower surface of the chip is pushed up with a columnar pin having a smaller diameter than an outline of the chip through the sheet, while an upper surface of the chip is held under suction by a collet.

In such a conventional pickup device, in a case in which the chip is less likely to be separated from the sheet due to a strong holding force of the chip by the sheet, it can be considered that an amount of protrusion of the pin (that is, a lifting amount) is increased. However, when the amount of protrusion of the pin is increased too much, breakage of the chip may become more likely to occur.

### SUMMARY OF THE INVENTION

The present invention has been made in light of the abovementioned problems, and one object of the present invention is to reduce the possibility of breakage of the chip when the chip fixed onto the sheet is picked up.

In accordance with an aspect of the present invention, there is provided a pickup method of picking up a chip fixed to one surface of a sheet from the sheet. The pickup method includes adjusting a relative position of an ejector mechanism and the chip, the ejector mechanism including a housing having a holding surface at a distal end portion thereof, the holding surface capable of applying a holding force to another surface of the sheet, and a pin having a movable tip end portion, the tip end portion of the pin being movable between a protrusion position at which the tip end portion of the pin moves upward from the holding surface and a retracted position at which the tip end portion of the pin does not move upward from the holding surface and is retracted in the housing, in a predetermined plane perpendicular to a direction in which the pin moves between the protrusion position and the retracted position, in such a manner that the pin is positioned at a first position of the chip which is movable upward to push up the chip through the sheet from the other surface of the sheet at the protrusion position, applying the holding force to the holding surface with the tip end portion of the pin being positioned in the retracted position and holding the other surface of the sheet on the holding surface, after the pin is positioned at the first position in the predetermined plane and the other surface of the sheet is held on the holding surface, moving the tip end portion of the pin to the protrusion position while holding the other surface of the sheet on the holding surface is maintained, and pushing up the chip with the pin, thereby peeling off part of the chip from the sheet, after the part of the chip is peeled off from the sheet, adjusting the relative position between the ejector mechanism and the chip, in such a manner that the pin is positioned at a second position of the chip different from the first position in the predetermined plane while holding the other surface of the sheet on the holding surface and the pushing up the chip with the pin having the tip end portion positioned at the protrusion position are maintained, thereby enlarging a peel-off region where the chip is at least partially peeled off from the sheet, and, after the pin is moved to the second position, holding the chip with a collet and separating the chip from the sheet, and picking up the chip.

In accordance with another aspect of the present invention, there is provided a test method of measuring a load applied when a chip fixed to one surface of a sheet is broken after the chip is picked up from the sheet. The test method includes adjusting a relative position of an ejector mechanism and the chip, the ejector mechanism including a housing having a holding surface at a distal end portion thereof, the holding surface capable of applying a holding force to another surface of the sheet, and a pin having a movable tip end portion, the tip end portion of the pin being movable between a protrusion position at which the tip end portion of the pin moves upward from the holding surface and a retracted position at which the tip end portion of the pin does not move upward from the holding surface and is retracted in the housing, in a predetermined plane perpendicular to a direction in which the pin moves between the protrusion position and the retracted position, in such a manner that the pin is positioned at a first position of the chip which is movable upward to push up the chip through the sheet from the other surface of the sheet at the protrusion position, applying the holding force to the holding surface with the tip end portion of the pin being positioned at the retracted position and holding the other surface of the sheet on the holding surface, after the pin is positioned at the first position in the predetermined plane and the other surface of the sheet is held on the holding surface, moving the tip end portion of the pin to the protrusion position while holding the other surface of the sheet on the holding surface is maintained, and pushing up the chip with the pin, thereby peeling off part of the chip from the sheet, after the part of the chip is peeled off from the sheet, adjusting the relative position between the ejector mechanism and the chip, in such a manner that the pin is positioned at a second position of the chip different from the first position in the predetermined plane while holding the other surface of the sheet on the holding surface and the pushing up the chip with the pin having the tip end portion positioned at the protrusion position are maintained, thereby enlarging a peel-off region where the chip is at least partially peeled off from the sheet, after the pin is moved to the second position, holding the chip with a collet and separating the chip from the sheet, and picking up the chip, after the chip is picked up from the sheet, pressing the chip with an indenter to break the chip, and measuring the load applied to the indenter when the chip is broken.

In accordance with a further aspect of the present invention, there is provided a pickup device which picks up a chip fixed to one surface of a sheet. The pickup device includes a sheet holding unit configured to hold the sheet, an ejector mechanism including a housing having a holding surface at a distal end portion thereof, the holding surface capable of applying a holding force to another surface of the sheet held by the sheet holding unit, and a pin having a movable tip end portion, the tip end portion of the pin being movable between a protrusion position at which the tip end portion of the pin moves upward from the holding surface and a retracted position at which the tip end portion of the pin does not move upward from the holding surface and is retracted in the housing, a moving unit which moves the ejector mechanism and the sheet held by the sheet holding unit relative to each other, a pickup unit having a collet to hold the chip with the collet and separate the chip from the sheet, and a controller which has a processor and a memory, and which controls the sheet holding unit, the ejector mechanism, the moving unit, and the pickup unit. When the collet picks up the chip from the sheet, the controller performs adjusting, by the moving unit, a relative position of the ejector mechanism and the chip, in a predetermined plane perpendicular to a direction in which the pin moves between the protrusion position and the retracted position, in such a manner that the pin is positioned at a first position of the chip which is movable upward to push up the chip through the sheet from the other surface of the sheet at the protrusion position, applying the holding force to the holding surface with the tip end portion of the pin being positioned in the retracted position and holding the other surface of the sheet on the holding surface, after the pin is positioned at the first position in the predetermined plane and the other surface of the sheet is held on the holding surface, moving the tip end portion of the pin to the protrusion position while holding the other surface of the sheet on the holding surface is maintained, and pushing up the chip with the pin, thereby peeling off part of the chip from the sheet, after the part of the chip is peeled off from the sheet, adjusting, by the moving unit, the relative position between the ejector mechanism and the chip, in such a manner that the pin is positioned at a second position of the chip different from the first position in the predetermined plane while holding the other surface of the sheet on the holding surface and the pushing up the chip with the pin having the tip end portion positioned at the protrusion position are maintained, thereby enlarging a peel-off region where the chip is at least partially peeled off from the sheet, and, after the pin is moved to the second position, holding the chip with the collet of the pickup unit and separating the chip from the sheet, and picking up the chip.

In accordance with a still further aspect of the present invention, there is provided a test apparatus which measures a load applied when a chip fixed to one surface of a sheet is broken after the chip is picked up from the sheet. The test apparatus includes a sheet holding unit which holds the sheet, an ejector mechanism including a housing having a holding surface at a distal end portion thereof, the holding surface capable of applying a holding force to another surface of the sheet held by the sheet holding unit, and a pin having a movable tip end portion, the tip end portion of the pin being movable between a protrusion position at which the tip end portion of the pin moves upward from the holding surface and a retracted position at which the tip end portion of the pin does not move upward from the holding surface and is retracted in the housing, a moving unit which moves the ejector mechanism and the sheet held by the sheet holding unit relative to each other, a pickup unit having a collet to hold the chip with the collet and separate the chip from the sheet, an indenter which breaks the chip picked up from the sheet, a load measuring unit which measures the load applied to the indenter when the indenter breaks the chip, and a controller which has a processor and a memory, which controls the sheet holding unit, the ejector mechanism, the moving unit, the pickup unit, and the indenter, and which receives output from the load measuring unit. When the collet picks up the chip from the sheet, the controller performs adjusting, by the moving unit, a relative position of the ejector mechanism and the chip, in a predetermined plane perpendicular to a direction in which the pin moves between the protrusion position and the retracted position, in such a manner that the pin is positioned at a first position of the chip which is movable upward to push up the chip through the sheet from the other surface of the sheet at the protrusion position, applying the holding force to the holding surface with the tip end portion of the pin being positioned at the retracted position and holding the other surface of the sheet on the holding surface, after the pin is positioned at the first position in the predetermined plane and the other surface of the sheet is held on the holding surface, moving the tip end portion of the pin to the protrusion position while holding the other surface of the sheet on the holding surface is maintained, and pushing up the chip with the pin, thereby peeling off part of the chip from the sheet, after the part of the chip is peeled off from the sheet, adjusting, by the moving unit, the relative position between the ejector mechanism and the chip, in such a manner that the pin is positioned at a second position of the chip different from the first position while holding the other surface of the sheet on the holding surface and the pushing up the chip with the pin having the tip end portion positioned at the protrusion position are maintained in the predetermined plane, thereby enlarging a peel-off region where the chip is at least partially peeled off from the sheet, and, after the pin is moved to the second position, holding the chip with the collet of the pickup unit and separating the chip from the sheet, and picking up the chip, and, after the collet picks up the chip from the sheet. The controller performs pressing the chip with the indenter to break the chip, and, when the chip is broken, causing the load measuring unit to measure the load applied to the indenter.

In the pickup method according to the aspect of the present invention and the pickup device according to the other aspect of the present inventio, by adjusting the relative position between the ejector mechanism and the chip in such a manner that the pin is positioned at the second position different from the first position in the predetermined plane while holding the other surface of the sheet on the holding surface and pushing up the chip with the pin positioned at the protrusion position are maintained, the peel-off region where the chip is at least partially peeled off from the sheet is enlarged. Hence, compared to a case in which the protrusion amount of the pin is increased, it is possible to reduce damage to the chip applied when the chip is picked up from the sheet. That is, it is possible to reduce the possibility of breakage of the chip while the peeling of the chip from the sheet is reliably ensured by enlarging the peel-off region, compared to a case in which the protrusion amount of the pin is increased.

In the test method according to the further other aspect of the present invention and the test apparatus according to the still further other aspect of the present invention, the chip picked up in the pickup method described above is pressed by the indenter to break the chip, and when the chip is broken, the load applied to the indenter is measured. Since it is possible to reduce the damage to the chip applied when the chip is picked up from the sheet, an original bending strength of the chip can more accurately be measured.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting an example of a test apparatus;

FIG. 2 is a perspective view depicting a chip unit;

FIG. 3A is a perspective view depicting a state in which a top portion of a pin protrudes upward;

FIG. 3B is a perspective view depicting a state in which the top portion of the pin is housed;

FIG. 3C is an enlarged cross-sectional view depicting the top portion of the pin;

FIG. 4 is a flowchart indicating a test method;

FIG. 5 is a view depicting the manner in which a first camera unit images a chip;

FIG. 6A is a view depicting the manner in which the pin is positioned immediately below a first corner of the chip and another surface of a sheet is held under suction on a holding surface of an ejector mechanism;

FIG. 6B is a partly enlarged view of FIG. 6A;

FIG. 6C is a perspective view of FIG. 6B;

FIG. 7A is a view depicting the manner in which the pin pushes up the chip to peel off part of the chip from the sheet;

FIG. 7B is a partly enlarged view of FIG. 7A;

FIG. 7C is a perspective view of FIG. 7B;

FIG. 8A is a perspective view depicting the manner in which a peel-off region is enlarged;

FIG. 8B is a partially cross-sectional side view of FIG. 8A;

FIG. 9 is a perspective view depicting the manner in which the peel-off region is further enlarged;

FIG. 10A is a view depicting the manner in which the pin pushes up the chip and a collet holds under suction the chip;

FIG. 10B is a view depicting the manner in which the collet picks up the chip;

FIG. 11 is a view depicting the manner in which the pickup unit moves the chip;

FIG. 12A is a view depicting the manner in which a non-suction surface of the chip is imaged;

FIG. 12B is a view depicting the manner in which a side surface of the chip is imaged;

FIG. 13 is a view depicting the manner in which the chip is supported by a pair of support portions; and

FIG. 14 is a view depicting the manner in which the chip is pressed by an indenter and a load applied to the indenter upon breaking the chip is measured by a load measuring unit.

### DETAILED DESCRIPTION OF THE PREFERRED EMBODIMENT

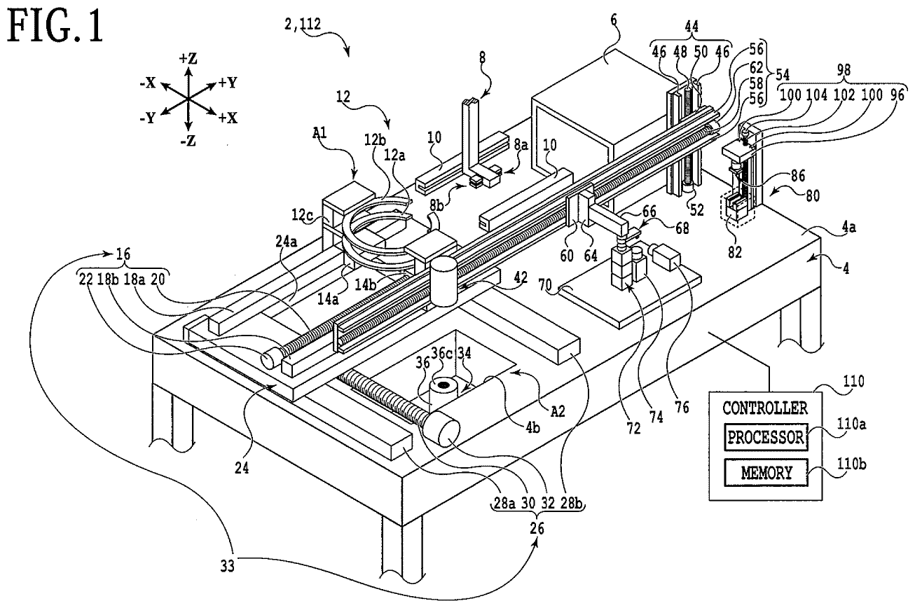

An embodiment according to an aspect of the present invention is described with reference to the accompanying drawings. FIG. 1 is a perspective view depicting an example of a test apparatus 2. The test apparatus 2 includes a pickup device 112 as described below. FIG. 1 depicts some of components of the test apparatus 2 simply in functional blocks.

An X-axis, a Y-axis, and a Z-axis depicted in FIG. 1 are orthogonal to each other. The X-axis is parallel to a +X direction and a −X direction that are opposite to each other. Similarly, the Y-axis is parallel to a +Y direction and a −Y direction that are opposite to each other, and the Z-axis is parallel to a +Z direction and a -Z direction that are opposite to each other. In the present specification, the +X direction and the −X direction are collectively referred to as the X-axis direction, the +Y direction and the −Y direction are collectively referred to as the Y-axis direction, and the +Z direction and the −Z direction are collectively referred to as the Z-axis direction. By way of example, the −Z direction is synonymous with a vertical direction, and an XY plane defined by the X-axis direction and the Y-axis direction is parallel to a horizontal surface and orthogonal to the Z-axis direction.

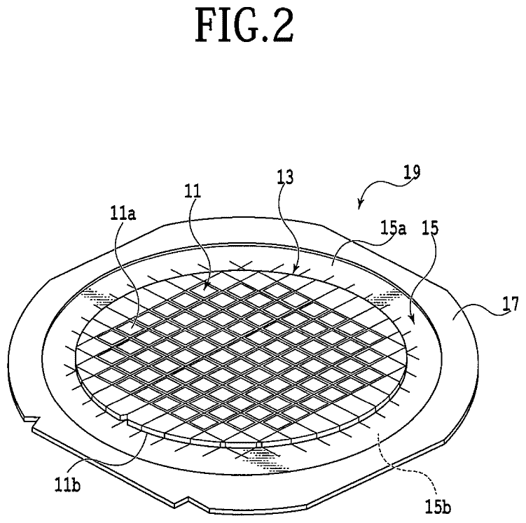

The test apparatus 2 has a base 4. When the base 4 is viewed from above, there is provided an undepicted cassette elevator for lifting a cassette 6 in the vicinity of a corner portion positioned on the −X direction and +Y direction sides of one surface 4a of the base 4. On the cassette elevator, there is placed the cassette 6, and the cassette 6 houses a chip unit 19 including a plurality of chips 11 (see FIG. 2) each serving as a test piece therein.

FIG. 2 schematically depicts the chip unit 19 in perspective. The plurality of chips 11 are manufactured by, for example, dividing a semiconductor wafer 13 such as a silicon wafer into multiple pieces, with use of a processing apparatus (not depicted) such as a cutting apparatus, a laser processing apparatus, or a grinding apparatus. FIG. 2 depicts a state in which the semiconductor wafer 13 is divided in to a plurality of chips 11. Devices such as integrated circuits (ICs) are formed in the vicinity of a front surface 11a of each chip 11. However, the devices may not necessarily be formed in the chip 11. The plurality of chips 11 are fixed to one surface 15a of a sheet 15 made of resin.

The sheet 15 is formed of a resin that is substantially transparent to light in a visible wavelength range and is significantly thin (for example, has a thickness of 1 mm or less). The sheet 15 according to the present embodiment is generally called an adhesive tape in which a sticky layer made of resin and a base layer made of resin are stacked. The sticky layer is formed of, for example, an epoxy-based, acrylic-based, or rubber-based adhesive, and the sticky layer may adopt an ultraviolet curable resin that cures upon exposure to ultraviolet light. Also, the base layer is formed of, for example, a resin such as polyolefin or polyvinyl chloride.

The sheet 15 has the sticky layer exposed at the one surface 15a thereof, and the sheet 15 has the base layer exposed at the other surface 15b thereof. However, the sheet 15 may include no sticky layer and may have only the base layer formed of thermoplastic resin. In this case, the semiconductor wafer 13 is fixed to the sheet 15 by thermocompression bonding. In addition, the plurality of chips 11 manufactured by dividing the semiconductor wafer 13 also remain fixed to the sheet 15.

The chip unit 19 having the plurality of chips 11, the sheet 15, and the ring frame 17 is configured such that one surface of a metal ring frame 17 is fixed to an outer peripheral portion of the one surface 15a of the sheet 15 and the plurality of chips 11 are supported by the ring frame 17 via the sheet 15.

Referring back to FIG. 1, there is provided a transfer unit 8 in the vicinity of the cassette elevator. The transfer unit 8 includes an arm having a substantially L shape when the test apparatus 2 is viewed from an XZ plane, and a moving mechanism (not depicted) coupled to the arm. The moving mechanism of the transfer unit 8 includes, for example, a ball screw and a servomotor for moving the arm in the Y-axis direction, as well as a ball screw and a servomotor for moving the arm in the Z-axis direction, and the like. The moving mechanism is operated, thereby causing the arm to move either in the Y-axis direction and the Z-axis direction.

In the arm of the transfer unit 8, a clamp mechanism 8a is provided on a side surface of the arm on the +Y direction side, and a clamp mechanism 8b is provided on a side surface of the arm on the −Y direction side. Each of the clamp mechanisms 8a and 8b has a pair of thin plate portions. The pair of thin plate portions are configured so as to be close to and apart from each other in the Z-axis direction. Each of the clamp mechanisms 8a and 8b can sandwich the ring frame 17 of the chip unit 19 with the pair of thin plate portions.

In a top plan view of the test apparatus 2, a pair of temporary rails 10 extending in the Y-axis direction are provided on the one surface 4a of the base 4. The pair of temporary rails 10 are disposed so as to sandwich the arm of the transfer unit 8 in the X-axis direction. The pair of temporary rails 10 have the chip unit 19 unloaded from the cassette 6 by the transfer unit 8 placed thereon.

More specifically, in such a manner that the chip unit 19 is positioned at a height corresponding to the pair of temporary rails 10, the cassette elevator is lifted, and then, the arm of the transfer unit 8 is moved such that one end of the ring frame 17 is positioned between the pair of thin plate portions of the clamp mechanism 8a. Subsequently, in a state in which the clamp mechanism 8a holds the one end of the ring frame 17, the arm is moved in the −Y direction until the chip unit 19 is placed on the temporary rails 10. Then, the pair of thin plate portions of the clamp mechanism 8a are caused to be spaced apart from the ring frame 17, so that the transfer of the chip unit 19 from the cassette 6 to the pair of temporary rails 10 is ended.

In a region on the −Y direction side relative to the pair of temporary rails 10, there is provided a sheet holding unit 12. The sheet holding unit 12 according to the present embodiment includes a frame support portion 12a and a frame pressing portion 12b that are opposed to each other in the Z-axis direction. Each of the frame support portion 12a and the frame pressing portion 12b has an annular ring shape with an inner diameter substantially equal to an inner diameter of the ring frame 17. However, a portion of the ring shape positioned on the +Y direction side as viewed from the center of the ring is cut out, and the ring shape has a C shape in top plan view. Such a cutout region serves as a moving path of the transfer unit 8.

The chip unit 19 pushed out from the pair of temporary rails 10 is placed on the frame support portion 12a. When the chip unit 19 is drawn out from the pair of temporary rails 10 and placed on the frame support portion 12a, first, the arm of the transfer unit 8 is moved such that the end portion of the ring frame 17 on the +Y direction side is positioned between the pair of thin plate portions of the clamp mechanism 8b. Next, the pair of thin plate portions of the clamp mechanism 8b hold the end portion of the ring frame 17 on the +Y direction side therebetween. Then, the arm is moved in the −Y direction until the chip unit 19 is placed on the frame support portion 12a. After that, the pair of thin plate portions of the clamp mechanism 8b are caused to be apart from the ring frame 17, and accordingly, transfer of the chip unit 19 from the pair of temporary rails 10 to the frame support portion 12a is ended.

The sheet holding unit 12 includes a driving mechanism 12c, such as an air actuator, that makes the frame support portion 12a and the frame pressing portion 12b close to each other and apart from each other in the Z-axis direction. When the driving mechanism 12c is actuated to make the frame support portion 12a and the frame pressing portion 12b close to each other, the ring frame 17 is sandwiched between the frame support portion 12a and the frame pressing portion 12b.

The sheet holding unit 12 holds the plurality of chips 11, the sheet 15, and the ring frame 17 in this manner. Note that the sheet holding unit 12 is not limited to one having the frame support portion 12a, the frame pressing portion 12b, the driving mechanism 12c, and the like. The sheet holding unit 12 may have a cylindrical suction table (not depicted) whose holding surface positioned on an upper end thereof is provided with a suction groove or a suction port. In a case in which the sheet holding unit 12 has the suction table, the sheet holding unit 12 holds under suction one surface of the ring frame 17 (that is, a surface to which the one surface 15a of the sheet 15 is attached) by a negative pressure.

In contrast, in a case in which the chip unit 19 has no ring frame 17 and includes the plurality of chips 11 and the sheet 15, the sheet holding unit 12 may hold the outer peripheral portion of the circular sheet 15 with the frame support portion 12a and the frame pressing portion 12b therebetween, and the outer peripheral portion of the other surface of the 15b of the circular sheet 15 may be hold under suction on the holding surface of the cylindrical suction table. In addition, the shape of the sheet 15 is not limited to a circular shape, and may be a rectangular shape. In this case, the sheet holding unit 12 may hold the sheet 15 by clamping peripheries of four side end portions of the sheet 15 by four clamping portions (not depicted) in the Z-axis direction, and hold under suction the outer peripheral portion of the sheet 15 (that is, the peripheries of the four side end portions) on a holding surface of a rectangular tube-like suction table (not depicted). Specifically, the sheet 15 can be stretched to such a degree that each of the chips 11 does not come into contact with an adjacent chip 11 and the sheet 15 does not have wrinkles, and accordingly, it is possible to optically observe the plurality of chips 11 from above. Moreover, as long as the sheet holding unit 12 does not interfere with an ejector mechanism 34 to be described later, it can take various modes.

In the example depicted in FIG. 1, the driving mechanism 12c is coupled with the Y-axis direction moving mechanism 16 via a pair of moving blocks 14a and 14b which are apart from each other in the X-axis direction. The Y-axis direction moving mechanism 16 has a pair of Y-axis direction guide rails 18a and 18b which are disposed along the Y-axis direction to be spaced apart from each other in the X-axis direction. The Y-axis direction guide rail 18a has the moving block 14a slidably coupled therewith in the Y-axis direction, and the Y-axis direction guide rail 18b has the moving block 14b slidably coupled therewith in the Y-axis direction.

Between the pair of Y-axis direction guide rails 18a and 18b, there is provided a screw shaft 20 whose longitudinal portion is arranged along the Y-axis. The screw shaft 20 is disposed in the vicinity of the Y-axis direction guide rail 18b. A nut portion (not depicted) is provided to the moving block 14b. The screw shaft 20 is coupled to this nut portion in a rotatable manner through a plurality of balls (not depicted). The screw shaft 20 has one end portion coupled to a motor 22 such as a servomotor. When the motor 22 is actuated, the sheet holding unit 12 is moved in the Y-axis direction along with the pair of moving blocks 14a and 14b.

The Y-axis direction moving mechanism 16 is fixed to an X-axis direction moving frame 24. The X-axis direction moving frame 24 has a pair of X-axis direction extension portions each of which is disposed in the X-axis direction, and a pair of Y-axis direction extension portions each of which is disposed in the Y-axis direction. The pair of X-axis direction extension portions and the pair of Y-axis direction extension portions constitute a rectangular through hole 24a. On one of the Y-axis direction extension portions, the Y-axis direction guide rail 18a is provided, and, on the other of the Y-axis direction extension portion, the Y-axis direction guide rail 18b is provided. In the present embodiment, the shorter one of a short side of the through hole 24a and a distance between the pair of Y-axis direction guide rails 18a and 18b in the X-axis direction is equal to or larger than an inner diameter of the frame support portion 12a and the frame pressing portion 12b.

Below the X-axis direction moving frame 24, there is provided an X-axis direction moving mechanism 26 which moves the X-axis direction moving frame 24 in the X-axis direction. The X-axis direction moving mechanism 26 has a pair of X-axis direction guide rails 28a and 28b which are disposed along the X-axis direction and are spaced apart from each other in the Y-axis direction. One of the X-axis direction extension portions of the X-axis direction moving frame 24 is slidably attached on the X-axis direction guide rails 28a in the X-axis direction, and the other of the X-axis direction extension portions of the X-axis direction moving frame 24 is slidably attached on the X-axis direction guide rails 28b in the X-axis direction.

One of the pair of X-axis direction extension portions of the X-axis direction moving frame 24, which is positioned above X-axis direction guide rails 28a, has a nut portion (not depicted) provided at a lower surface thereof. A threaded shaft 30 disposed along the X-axis direction is rotatably coupled to this nut portion via a plurality of balls (not depicted). The screw shaft 30 has one end portion coupled to a motor 32 such as a servomotor. When the motor 32 is actuated, the X-axis direction moving frame 24 is moved in the X-axis direction. The Y-axis direction moving mechanism 16 and the X-axis direction moving mechanism 26 function as a moving unit 33 which moves the chip unit 19 (that is, the sheet 15) held by the sheet holding unit 12 in the X-axis and Y-axis directions, respectively.

The moving unit 33 according to the present embodiment moves the sheet holding unit 12 between a receiving region A1 where the sheet holding unit 12 receives the chip unit 19 from the transfer unit 8 and a pickup region A2 where a pickup unit 68 to be described below picks up a chip 11 from the chip unit 19.

On the one surface 4a of the base 4, there is provided a rectangular opening 4b in the vicinity of the corner portion positioned in the +X direction and the −Y direction as viewed from the center thereof. In the opening 4b, the ejector mechanism 34 is provided. The ejector mechanism 34 has a cylindrical housing 36.

In the test apparatus 2 according to the present embodiment, the position of the ejector mechanism 34 is fixed. Hence, when the moving unit 33 described above moves the sheet holding unit 12, the ejector mechanism 34 and the sheet 15 held by the sheet holding unit 12 can be moved relative to each other in the XY plane (that is, a predetermined plane).

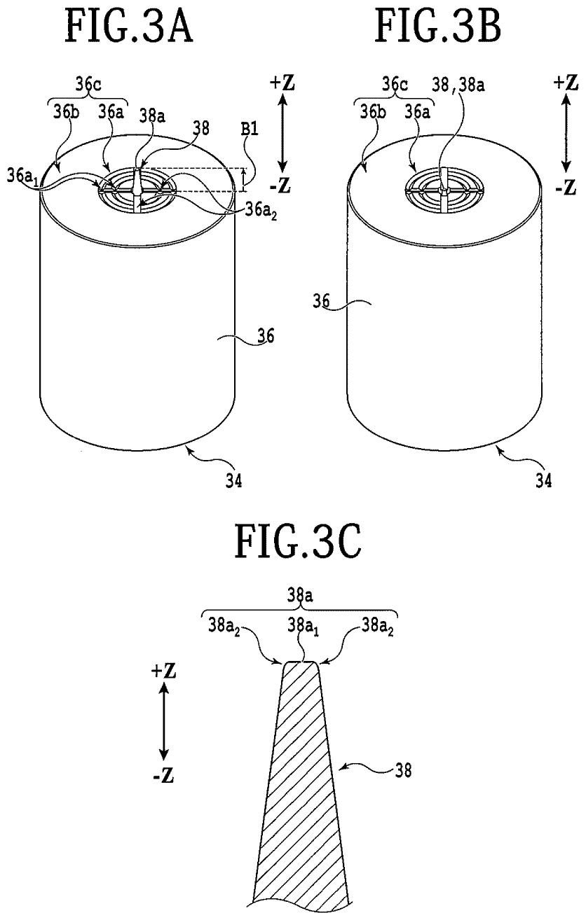

Here, with reference to FIG. 3A and FIG. 3B, the ejector mechanism 34 will be described. The ejector mechanism 34 has a circular central region 36a which is capable of holding under suction the sheet 15 by a negative pressure and an annular outer peripheral region 36b provided so as to surround the central region 36a, in top plan view, to support the sheet 15, at a top portion of the housing 36 (that is, a distal end portion). The central region 36a and the outer peripheral region 36b constitute a holding surface 36c which can apply a holding force by a negative pressure to the other surface 15b of the sheet 15. The central region 36a includes a plurality of first grooves 36a₁ disposed concentrically with each other and a plurality of linear second grooves 36a₂ disposed so as to get across each of the plurality of first grooves 36a₁ and cross each other.

In the central region 36a, a suction source such as a vacuum pump (not depicted) and an air supply source (not depicted) which supplies compressed air (not depicted) can selectively be communicated with each other via a solenoid valve (not depicted) operation of which is controlled by a controller 110 to be described later. When the negative pressure from the suction source is transmitted to the central region 36a, the other surface 15b of the sheet 15 positioned on the holding surface 36c is held under suction on the holding surface 36c. In addition, when the air from the air supply source is supplied to the central region 36a after the other surface 15b of the sheet 15 is held under suction on the holding surface 36c, the central region 36a is returned to normal pressure, and the suction force acting to the holding surface 36c disappears.

At a position where the plurality of first grooves 36a₁ and the plurality of second grooves 36a₂ cross each other, a cylindrical space along the Z-axis direction is provided. In this cylindrical space, a pin 38 also referred to as a needle is provided.

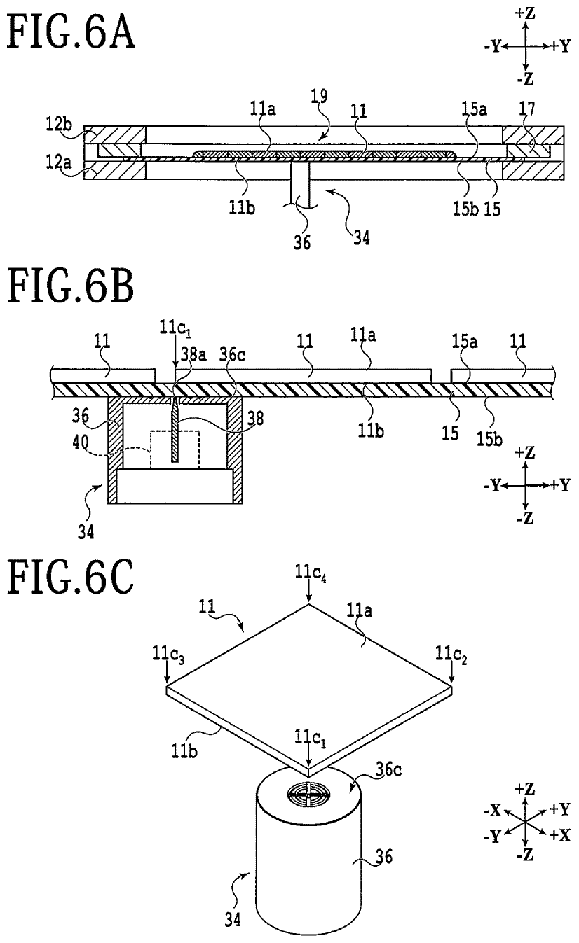

Inside the housing 36, in order to move the pin 38 in the Z-axis direction, a driving section 40 such as an air cylinder and a servomotor (see FIG. 6B and the like) is provided. According to the operation of the driving section 40, the pin 38 is movable in the Z-axis direction. A top portion (that is, a tip end portion) 38a of the pin 38 is movable between a protrusion position where the top portion 38a protrudes from the holding surface 36c by a predetermined distance B1 (see FIG. 3A) and a retracted position where the top portion 38a of the pin 38 does not protrude from the holding surface 36c and is housed in the housing 36 (see FIG. 3B).

In the present embodiment, a moving direction of the pin 38 between the protrusion position and the retracted position is substantially parallel to the Z-axis direction. Meanwhile, the moving unit 33 adjusts a position of the pin 38 in the XY plane (that is, a predetermined plane) relative to the chip 11 held by the sheet holding unit 12.

FIG. 3A is a perspective view depicting the ejector mechanism 34 in a state in which the top portion 38a of the pin 38 protrudes by the predetermined distance B1, and FIG. 3B is a perspective view depicting the ejector mechanism 34 in a state in which the top portion 38a of the pin 38 is retracted in the housing 36. FIG. 3C is an enlarged cross-sectional view of the top portion 38a of the pin 38.

The pin 38 is formed of, for example, a metal material such as stainless steel and has a tapered shape that becomes narrower in the +Z direction. The top portion 38a of the pin 38 has a substantially flat and circular central region 38a₁ with a diameter of approximately 0.1 to 0.4 mm and an annular and protruding curved surface region 38a₂ which surrounds the central region 38a₁. By making the central region 38a₁ substantially flat, compared to a case of making the central region 38a₁ a spherical protruding region, it is possible to increase an area of pushing the chip 11, allowing damage to the chip 11 to be reduced.

Moreover, as described later, in the present embodiment, in a state in which the pin 38 pushes the chip 11 upward, the pin 38 is moved in the X-axis direction and the Y-axis direction. Accordingly, by making the surroundings of the central region 38a₁ the curved surface region 38a₂, compared to a case of making the top portion 38a of the pin 38 cylindrical or prismatic, it is possible to reduce the possibility that the pin 38 hooks onto the sheet 15. Further, since it is possible to reduce the possibility that the pin 38 hooks onto the sheet 15, it is also possible to reduce the possibility that, when the pin 38 disengages with the sheet 15, the pin 38 may hit the chip 11 in an unexpected direction due to the rebound.

Note that the pin 38 may include a double structure having a central portion which most protrudes upward and an outer peripheral portion that is disposed so as to surround this central portion and a protrusion amount of which is smaller than that of the central portion. In addition, the structure of the pin 38 is not limited to the double structure and may be a triple structure. The pin 38 of the triple structure has the central portion described above, a first outer peripheral portion which is disposed so as to surround the central portion and a protrusion amount of which is smaller than that of the central portion, and a second outer peripheral portion which is disposed so as to surround the first outer peripheral portion and a protrusion amount of which is smaller than that of the first outer peripheral portion.

Description will now return to FIG. 1. As depicted in FIG. 1, a first camera unit 42 is provided on the +Z direction side relative to the opening 4b. The first camera unit 42 has a first lens (not depicted) having an optical axis disposed along the Z-axis direction, and a first solid-state imaging device (not depicted) which performs photoelectric conversion on light focused through the first lens.

The first camera unit 42 successively images the front surface 11a of each of the chips 11 of the chip unit 19 held on the sheet holding unit 12. In the present embodiment, the controller 110 performs image processing on an image obtained by this imaging, and accordingly, in each of the chips 11, coordinates of the central position and coordinates of the outer peripheral edge (that is, the entire perimeter of the rectangular shape) in the XY plane are obtained. However, the controller 110 may obtain the coordinates of the central position and the coordinates of four corners of the outer peripheral edge in the XY plane through the image processing. In this case, the controller 110 appropriately calculates the coordinates other than the four corners of the chip 11 in the XY plane, for example, on the basis of the coordinates of the four corners of the outer peripheral edge.

Meanwhile, the Z-axis direction moving mechanism 44 is provided in the +X direction of the cassette elevator. The Z-axis direction moving mechanism 44 has a pair of Z-axis direction guide rails 46 which are disposed along the Z-axis direction and are apart from each other in the Y-axis direction. Between the pair of Z-axis direction guide rails 46, there is provided a screw shaft 48 whose longitudinal portion is arranged along the Z-axis direction. A Z-axis direction moving plate 50 is attached to the pair of Z-axis direction guide rails 46 on the +X direction side thereof so as to be slidable in the Z-axis direction.

On a back surface of the Z-axis direction moving plate 50, a nut portion (not depicted) is provided, and the screw shaft 48 is rotatably coupled to the nut portion via a plurality of balls. The screw shaft 48 has, at a lower end portion, a drive source 52 such as a servomotor provided. When the drive source 52 is actuated, the Z-axis direction moving plate 50 moves in the Z-axis direction with the nut portion.

A Y-axis direction moving mechanism 54 is mounted on a front surface of the Z-axis direction moving plate 50. The Y-axis direction moving mechanism 54 is positioned at substantially a center of the one surface 4a of the base 4 in the X-axis direction when the test apparatus 2 is viewed in plan.

The Y-axis direction moving mechanism 54 has a pair of Y-axis direction guide rails 56 which are disposed along the Y-axis direction and are apart from each other in the Z-axis direction. Between the pair of Y-axis direction guide rails 56, there is provided a screw shaft 58 whose longitudinal portion is arranged along the Y-axis direction. A Y-axis direction moving plate 60 is attached to the pair of guide rails 56 so as to be slidable in the Y-axis direction.

On a back surface of the Y-axis direction moving plate 60, a nut portion (not depicted) is provided. The screw shaft 58 is rotatably coupled to the nut portion via a plurality of balls. The screw shaft 58 has, at one end portion, coupled to a drive source 62 such as a servomotor provided. When the drive source 62 is actuated, the Y-axis direction moving plate 60 moves along the Y-axis direction.

On a front surface of the Y-axis direction moving plate 60, a raising and lowering mechanism 64 is provided. In FIG. 1, for convenience, the raising and lowering mechanism 64 is depicted as a rectangular parallelepiped, but the raising and lowering mechanism 64 may have a ball screw as in the Z-axis direction moving mechanism 44 and may have an air actuator such as an air cylinder. The raising and lowering mechanism 64 moves an arm 66 in the Z-axis direction (that is, raises and lowers the arm 66).

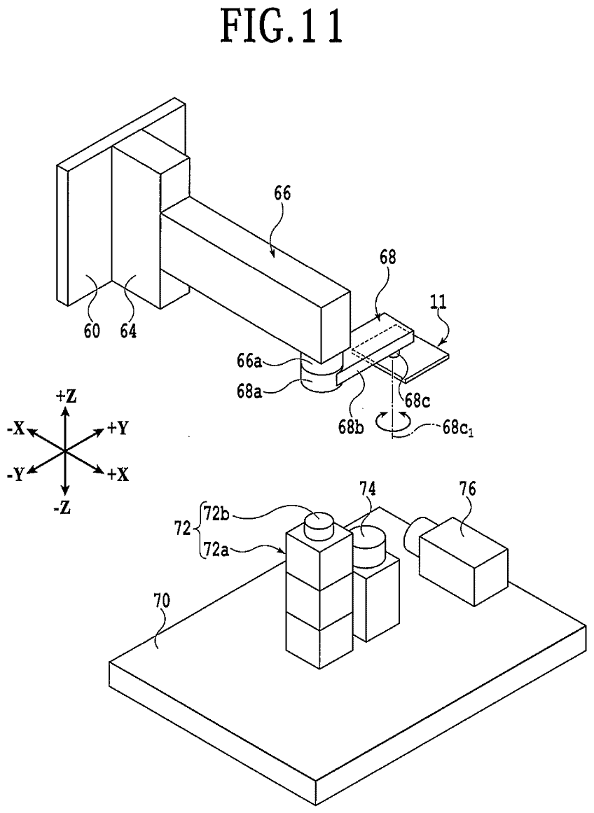

The arm 66 is disposed along the X-axis direction, and the arm 66 has its distal end portion provided with the pickup unit 68 including a collet 68c (see FIG. 11) which holds under suction the chip 11. Here, with reference to FIG. 11, the pickup unit 68 and the like will be described.

Below the distal end portion of the arm 66, a mounting portion 66a is provided. The mounting portion 66a has one end portion of a mounted portion 68a of the pickup unit 68 (in the present example, an upper end portion) mounted thereto in such a manner as to be detachably attached thereto by use of mechanical meshing between a protrusion and a recess. For example, each of the mounting portion 66a and the one end portion of the mounted portion 68a constitute a pneumatically or electrically driven hand changer, a tool changer, an automatic tool changer (ATC), and the like. However, an attachment mode for the mounting portion 66a and the one end portion of the mounted portion 68a is not limited to the mechanical meshing between the protrusion and the recess, and the mounting portion 66a and the one end portion of the mounted portion 68a may be detachably attached to each other by use of a suction force such as a negative pressure or an electromagnetic force.

The pickup unit 68 includes the mounted portion 68a, a plate-like support portion 68b a proximal end portion of which is fixed to the mounted portion 68a and which is disposed along the Y-axis direction, and the collet 68c which is provided on a lower surface of a distal end portion of the support portion 68b. The collet 68c in the present embodiment includes a cylindrical distal end portion, and this distal end portion has a cylindrical cavity portion (not depicted) through which a negative pressure is transmitted provided therein. Note that a diameter of the cavity portion is smaller than the shortest side of the chip 11. However, the shape of the distal end portion of the collet 68c is not limited to this example, and may take various other forms as long as the chip 11 can appropriately be held under suction.

A rotational drive source (not depicted) such as a servomotor or a stepping motor is provided within the support portion 68b. When this drive source is actuated, the collet 68c is rotated with a straight line extending along the Z-axis direction passing through the center of the cavity portion of the collet 68c as a rotational axis 68c₁.

The collet 68c is configured to be selectively communicated with a suction source (not depicted) such as a vacuum pump and an air supply source (not depicted) for supplying a compressed air via a flow channel, a pipe, and the like which are formed in the support portion 68b. Between the collet 68c and each of the suction source and the air supply source, there is provided a solenoid valve (not depicted) operation of which is controlled by the controller 110.

When the suction source is communicated with the collet 68c with the suction source being actuated, a negative pressure is transmitted to the distal end portion of the collet 68c (that is, a lower end thereof depicted in FIG. 11). Subsequently, when the air supply source is communicated with the collet 68c in a state in which the air supply source is actuated, the cavity portion of the distal end portion of the collet 68c is returned to normal pressure, and the negative pressure acting on the distal end portion of the collet 68c is lost. In this manner, the chip 11 is separated from the collet 68c.

On a portion of the one surface 4a on the +Y direction side relative to the opening 4b and on the +X direction side relative to the pair of temporary rails 10, there is provided a rectangular plate-like vibration isolation table 70 (see FIG. 1). On one surface of the vibration isolation table 70 (an upper surface in the present example), there is provided a moving mechanism 72.

The moving mechanism 72 in the present embodiment includes an XYZ stage 72a. On one surface of the XYZ stage 72a (an upper surface in the present example), there is provided a mounting portion 72b. The other end portion of the mounted portion 68a of the pickup unit 68 (the lower end portion in the present example) is detachably attached to the mounting portion 72b, by use of the mechanical meshing between the protrusion and the recess or the suction force such as the negative pressure or the electromagnetic force. The XYZ stage 72a can adjust the positions of the mounting portion 72b in the X-axis direction, the Y-axis direction, and the Z-axis direction.

A second camera unit 74 is provided on the +Y direction side of the moving mechanism 72. The second camera unit 74 images a non-suction surface (a lower surface in the present example) of the chip 11 held under suction by the collet 68c. The second camera unit 74 includes a second lens an optical axis of which is disposed substantially parallel to the Z-axis direction, and a second solid-state imaging device where light passing through the second lens is focused and which performs photoelectric conversion on the focused light.

On the +X direction side and the +Z direction side of the second camera unit 74, there is provided a third camera unit 76. The third camera unit 76 images a side surface of the chip 11 held under suction by the collet 68c (that is, an outer peripheral side surface between a sucked surface and the non-suction surface). The third camera unit 76 includes a third lens an optical axis of which is disposed substantially parallel to the X-axis direction, and a third solid-state imaging device where light passing through the third lens is focused and which performs photoelectric conversion on focused light. Rotating the collet 68c around the rotational axis 68c₁ causes the third camera unit 76 to image any side surface of four side surfaces of the chip 11.

According to images of damage, scratch, cracking, and the like in the chip 11, which are recorded with use of the second camera unit 74 and the third camera unit 76, before a destructive test to be described later is performed, history information on the chip 11 after being picked up and before being subjected to the destructive test can be kept.

Here, a procedure from when the chip 11 is picked up with the pickup unit 68 to when the non-suction surface and the side surfaces of the chip 11 are imaged will briefly be described.

First, the chip unit 19 having the sheet 15 held by the sheet holding unit 12 is moved to the pickup region A2 by the moving unit 33. Next, by use of the first camera unit 42, coordinates of the center position, the outer peripheral edge, and the like of each of the chips 11 in the test apparatus 2 are identified. Then, the pin 38 of the ejector mechanism 34 pushes up the corner portion of one of the chips 11 through the sheet 15 and while protrusion of the pin 38 is maintained, the chip unit 19 is moved relative to the pin 38 in the XY plane.

Owing to the relative movement of the pin 38, after an adhesive force between the relevant chip 11 and the sheet 15 is reduced, a relative position between the pickup unit 68 and the chip unit 19 in the XY plane is adjusted, and the relevant chip 11 is held under suction by the collet 68c. Then, by moving the collet 68c in the +Z direction, the relevant chip 11 is separated from the sheet 15 to pick up the relevant chip 11.

Subsequently, by moving the arm 66 and the pickup unit 68, the mounted portion 68a of the pickup unit 68 comes into contact with the mounting portion 72b of the moving mechanism 72. Then, the mounted portion 68a is detached from the mounting portion 66a of the arm 66 and is attached to the mounting portion 72b of the moving mechanism 72. Then, owing to the moving mechanism 72 and the drive source in the support portion 68b, and the like, the position of the chip 11 held under suction by the collet 68c is adjusted, the second camera unit 74 images the non-suction surface of the chip 11, and the third camera unit 76 images the side surfaces of the chip 11.

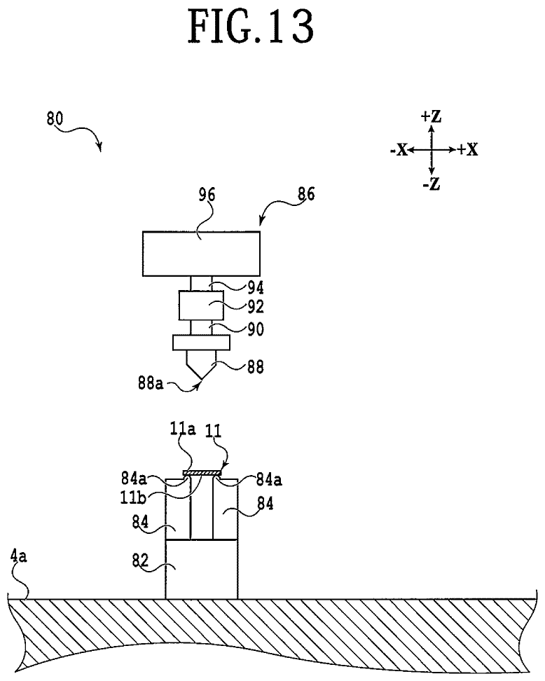

A test unit 80 which performs the three-point bending test on the chip 11 as a test piece is provided on the +Y direction side of the vibration isolation table 70 and the +X direction side of the cassette elevator. Here, the test unit 80 will be described with reference to FIG. 13. The three-point bending test is conducted, for example, in accordance with or in conformity with R1601:2008 of Japanese Industrial Standards (JIS), ISO 14704:2016 defined by International Organization for Standardization, G86-0303:2011 of Semiconductor Equipment and Materials International (SEMI) standards, and the like.

The test unit 80 has a base section 82 fixed to the one surface 4a of the base 4, and a pair of support portions 84 which are fixed onto the base section 82 and are provided apart from each other in the X-axis direction. In order to prevent scattering of fragments or the like generated by destruction, a rectangular prism-shaped cover member is provided in the periphery of the base section 82 and the pair of support portions 84 (see a rectangle depicted by a broken line in the periphery of the base section 82 in FIG. 1).

A receiving portion 84a in a semi-cylindrical shape in XZ plan view is provided at a top portion of each of the support portions 84. An upper end portion of each of the receiving portions 84a has a rounded shape, and has, for example, a curvature radius of 2.0 to 3.0 mm. The pair of receiving portions 84a correspond to, for example, support members defined by R1601:2008 of JIS. An apex of each of the pair of receiving portions 84a serves as a support point at which the chip 11 (that is, a test piece) is supported. A distance between the supporting points of the pair of receiving portions 84a is determined to be a predetermined distance according to the shape of the chip 11. The distance between the supporting points of the pair of receiving portions 84a is determined to be, for example, 30±0.1 mm or 40±0.1 mm.

The test unit 80 has a pressing unit 86 provided in the +Z direction side of the pair of support portions 84. The pressing unit 86 has a rod-like or plate-like indenter 88 a longitudinal portion of which is disposed along the Y-axis direction. The indenter 88 substantially corresponds to, for example, the support member defined by R1601:2008 of JIS. The indenter 88 has a tapered shape whose width in the X-axis direction becomes narrower toward the −Z direction, and has a substantially V shape in the XZ plan view. A distal end portion 88a of the indenter 88 (that is, a lower end portion) has a rounded shape, and has, for example, a curvature radius of 2.0 to 3.0 mm.

The indenter 88 has a proximal end portion fixed to a bottom portion of a load measuring unit 92 via a first connecting member 90 of a cylindrical shape. The load measuring unit 92 includes a load cell having a strain gauge, and a measuring instrument which converts an electric signal generated in the strain gauge into a load (unit: N). The measuring instrument of the load measuring unit 92 is electrically connected to the controller 110.

The load measuring unit 92 measures a load applied to the chip 11 when the indenter 88 presses the chip 11. Note that the measuring unit of the load measuring unit 92 may be part of the controller 110 and may not necessarily be provided in the pressing unit 86. However, the load cell is fixed to the indenter 88 directly or indirectly.

A top portion of the moving block load measuring unit 92 has a Z-axis direction moving block 96 fixed thereto via a cylindrical second connecting member 94. The Z-axis direction moving block 96 is configured so as to be movable along the Z-axis direction by the Z-axis direction moving mechanism 98, as depicted in FIG. 1.

The Z-axis direction moving mechanism 98 has a pair of Z-axis direction guide rails 100 disposed along the Z-axis direction. The Z-axis direction moving block 96 is slidably attached to the pair of Z-axis direction guide rails 100. Between the pair of Z-axis direction guide rails 100, a screw shaft 102 extending along the Z-axis direction is disposed. The screw shaft 102 is rotatably coupled to a nut portion (not depicted) provided in the Z-axis direction moving block 96, via a plurality of balls (not depicted). The screw shaft 102 has an upper end portion coupled to a drive source 104 such as a servomotor. When the drive source 104 is actuated, the indenter 88 moves along the Z-axis direction, with the Z-axis direction moving block 96. Operation of the indenter 88 in the Z-axis direction is controlled by the controller 110 controlling the Z-axis direction moving mechanism 98.

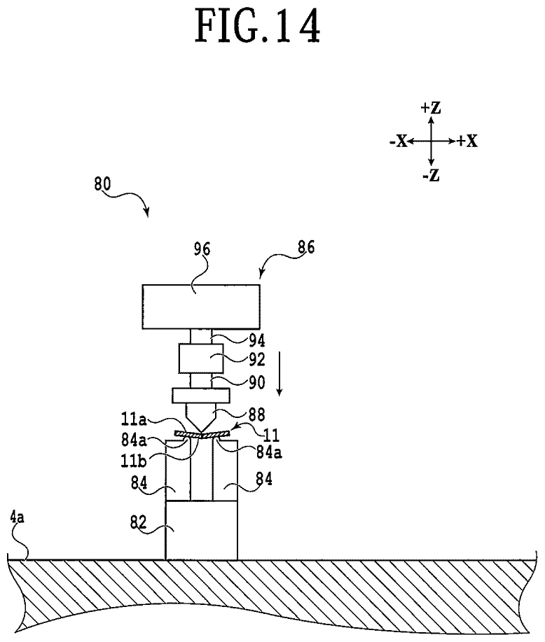

As depicted in FIG. 14, the distal end portion 88a of the indenter 88 is positioned at the substantially middle of the pair of receiving portions 84a in the X-axis direction and presses the front surface 11a of the chip 11 supported by the pair of receiving portions 84a, eventually destructing the chip 11. The load measuring unit 92 measures the load applied to the indenter 88 in real time. In addition, a measurement value obtained by the measuring instrument of the load measuring unit 92 is output to the controller 110 in real time, and the controller 110 receives the output from the measuring instrument in real time.

The load applied to the indenter 88 increases until the chip 11 is destructed and, when the chip 11 is completely broken, sharply decreases to become substantially zero. The controller 110 stores at least the maximum load measured during a period from when the indenter 88 gradually pushes into the chip 11 and the chip 11 is broken to when the load sharply decreases (that is, the load applied to the indenter 88 when the indenter 88 destructs the chip 11, and the load at a time of destructing the chip 11), and according to the following equation (1), calculates a bending strength (that is, a three-point bending strength σ).

$$σ = 3 PL / ( 2 {wt}^{2} ) \qquad ( 1 )$$

In the equation (1), P refers to the maximum load (unit: N) described above, L refers to the distance between the supporting points of the pair of receiving portions 84a (unit: mm), w refers to the width of the chip 11 (unit: mm) (in the present example, the length of the chip 11 in the Y-axis direction), and t refers to the thickness of the chip 11 (unit: mm) (that is, the length of the chip 11 in the Z-axis direction).

When the load is measured at a time of destructing the chip 11, first, the arm 66 is moved in such a manner that the mounting portion 66a of the arm 66 comes into contact with the mounted portion 68a of the pickup unit 68. Subsequently, the mounted portion 68a of the pickup unit 68 is detached from the mounting portion 72b of the moving mechanism 72 and attached to the mounting portion 66a of the arm 66. Thus, the pickup unit 68 holding the chip 11 under suction is delivered from the moving mechanism 72 to the arm 66. Then, in such a manner that the chip 11 is placed on the pair of support portions 84, the arm 66 and the pickup unit 68 are moved. Then, air is jetted from the air supply source in place of the vacuum pump, so that the chip 11 is separated from the collet 68c.

After the arm 66 and the pickup unit 68 are retracted from the test unit 80, the indenter 88 is gradually lowered, and the chip 11 is destructed. Accordingly, the load when the chip 11 is destructed is measured.

The test apparatus 2 includes the controller 110 for controlling the various components described above. The controller 110 includes a computer having a processor 110a, typically a central processing unit (CPU), and a memory 110b, for example. The memory 110b includes a main storage device such as a dynamic random access memory (DRAM) and an auxiliary storage device such as a flash memory, a hard disk drive, and a solid state drive.

The auxiliary storage device stores software including a predetermined program. Functions of the controller 110 are implemented by operating the processor 110a and the like according to the software. For example, the processor 110a reads a predetermined program from the memory 110b and executes the program, so that calculating the coordinates of the center position and the outer peripheral edge of the chip 11 by performing image processing on an image of the chip 11 captured by the first camera unit 42, moving the pin 38 relative to the chip 11, picking up the chip 11 by the collet 68c, imaging the non-suction surface of the chip 11 by the second camera unit 74 and imaging the side surfaces of the chip 11 by the third camera unit 76, and destructing the chip 11 by the indenter 88 and measuring the load when the chip 11 is destructed, for example, are carried out. Moreover, the memory 110b stores a program for calculating the equation (1) above, and the processor 110a executes this program, so that the bending strength is calculated.

Meanwhile, some of the components of the test apparatus 2 function as the pickup device 112 picking up the chip 11 from the sheet 15. The pickup device 112 includes the sheet holding unit 12, the moving unit 33, the ejector mechanism 34, the first camera unit 42, the Z-axis direction moving mechanism 44, the Y-axis direction moving mechanism 54, the raising and lowering mechanism 64, the arm 66, the pickup unit 68, and the controller 110.

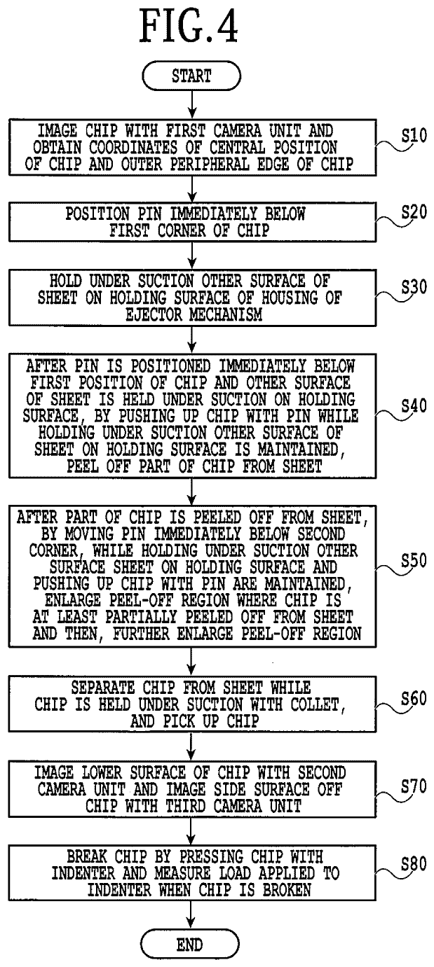

Next, with reference to FIG. 4 to FIG. 14, a test method in which, after the chip 11 is picked up from the sheet 15 by the pickup unit 68, the test unit 80 destructs the chip 11 and the load when the chip 11 is broken is measured will be described. FIG. 4 is a flowchart indicating the test method according to the present embodiment. According to the present embodiment, the steps are performed in the order of S10 to S80 in the test apparatus 2. Operation in each step is performed by the controller 110 appropriately controlling the components of the test apparatus 2. Note that this test method includes a pickup method of picking up the chip 11 from the sheet 15. More specifically, steps from S10 to S60 correspond to the pickup method.

The chip unit 19 unloaded from the cassette 6 and held by the sheet holding unit 12 is positioned to the pickup region A2 by the moving unit 33. The chip unit 19 in the present embodiment has been subjected to processing of reducing adhesion of the adhesive layer of the sheet 15 before being housed in the cassette 6 (for example, irradiation of an ultraviolet ray in a case in which the adhesive layer is an ultraviolet curable resin). However, in the test apparatus 2, an adhesion reduction process unit (for example, an ultraviolet irradiation unit) which reduces the adhesion of the adhesive layer of the sheet 15 may be provided between a cassette elevator on which the cassette 6 is placed and the pickup region A2.

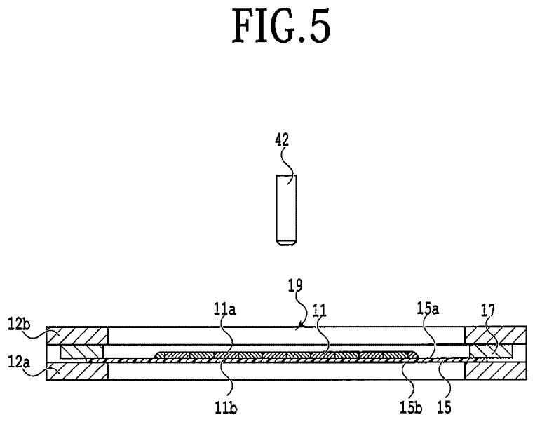

After the chip unit 19 is moved to the pickup region A2, as depicted in FIG. 5, the first camera unit 42 images the front surface 11a of the chip 11. FIG. 5 is a view depicting the manner in which the first camera unit 42 images the chip 11. Then, the controller 110 performs image processing, thereby obtaining the coordinates of the center position of each chip 11 in the XY plane and the coordinates of the outer peripheral edge of each chip 11 in the XY plane (imaging process S10).

Next, as depicted in FIG. 6A to FIG. 6C, in such a manner that the pin 38 is positioned at a position corresponding to one first corner (that is, a first position) 11c₁ of the four corners of one chip 11, a relative position between the ejector mechanism 34 and the chip 11 is adjusted in the XY plane (position adjusting step S20). In the present embodiment, the position of the pin 38 relative to the chip 11 in the XY plane is adjusted by the moving unit 33 in such a manner that the central region 38a₁ of the top portion 38a of the pin 38 (see FIG. 3C) is positioned immediately below the first corner 11c₁ of the chip 11.

Then, in a state in which the top portion 38a of the pin 38 is positioned at an retracted position (see FIG. 6B and FIG. 6C), the negative pressure is transmitted to the central region 36a, so that the suction force (that is, the holding force) is applied to the holding surface 36c, thereby holding under suction the other surface 15b of the sheet 15 on the holding surface 36c (holding step S30).

FIG. 6A is a view depicting the manner in which the pin 38 is positioned immediately below the first corner 11c₁ of the chip 11 and the other surface 15b of the sheet 15 is held under suction on the holding surface 36c of the ejector mechanism 34. FIG. 6B is a partly enlarged view of FIG. 6A. FIG. 6C is a perspective view of FIG. 6B. Note that, in FIG. 6C, in order to explicitly describe the ejector mechanism 34 and the pin 38, the sheet 15 is omitted. In addition, in FIG. 6C, the four corners of the chip 11 in top plan view (that is, the first corner 11c₁, the second corner 11c₂, the third corner (third position) 11c₃, and the fourth corner (fourth position) 11c₄) are depicted as well.

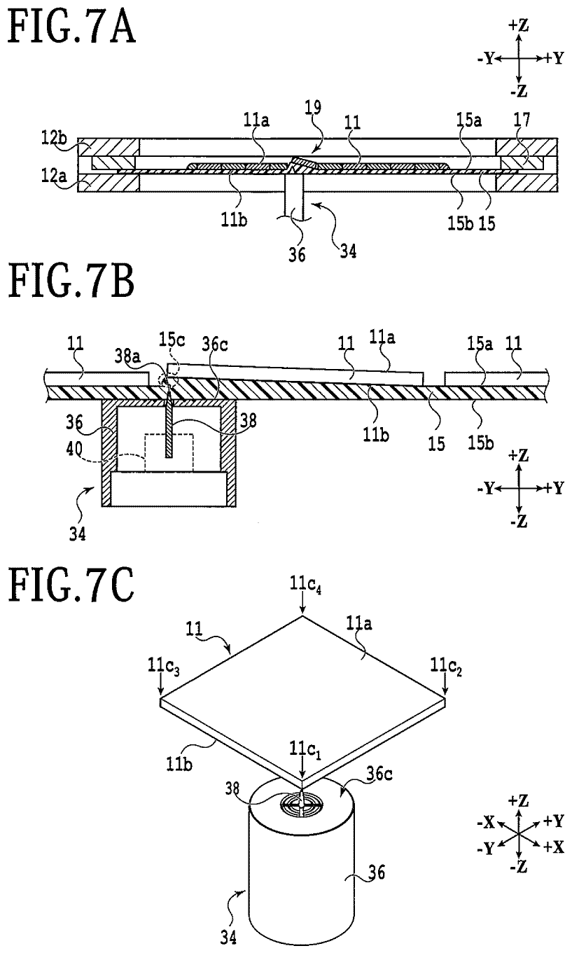

After the pin 38 is positioned at the first corner 11c₁, the driving section 40 moves the top portion 38a of the pin 38 to the protrusion position, and accordingly, the pin 38 can push up the chip 11 through the sheet 15 from the other surface 15b of the sheet 15. After the pin 38 is positioned at the first corner 11c₁ in the XY plane and the other surface 15b of the sheet 15 is held under suction on the holding surface 36c, as depicted in FIG. 7A to FIG. 7C, the top portion 38a of the pin 38 is moved to the protrusion position while holding under suction the other surface 15b of the sheet 15 on the holding surface 36c is maintained, and the chip 11 is pushed up. Accordingly, part of the chip 11 is peeled off from the sheet 15 (partly peeling step S40).

When the pin 38 pushes up the sheet 15, the other surface 15b of the sheet 15 is held under suction on the holding surface 36c, so that the sheet 15 is deformed in a state in which the other surface 15b of the sheet 15 is in contact with the holding surface 36c (see FIG. 7B). At this time, in association with the deformation of the sheet 15, the chip 11 is partly peeled off from the other surface 15b of the sheet 15 in the periphery of the first corner 11c₁ which is pushed up through the sheet 15. For example, in the vicinity of a region 15c in which the amount by which the sheet 15 is deformed is largest (see FIG. 7B), the chip 11 is peeled off from the one surface 15a of the sheet 15. Note that the region to be peeled off at this time may be a significantly narrow range. Meanwhile, when the pin 38 pushes up the sheet 15, the other surface 15b of the sheet 15 is held under suction on the holding surface 36c, resulting in an advantage of being capable of reducing the amount by which the back surface 11b of the chip 11 pushed up with the pin 38 is deformed, compared to a case in which the other surface 15b of the sheet 15 is not held under suction on the holding surface 36c.

FIG. 7A is a view depicting the manner in which the pin 38 pushes up the chip 11 to peel off part of the chip 11 from the sheet 15, FIG. 7B is a partly enlarged view of FIG. 7A, and FIG. 7C is a perspective view of FIG. 7B. Note that, in FIG. 7C, in order to explicitly describe the ejector mechanism 34 and the pin 38, the sheet 15 is omitted.

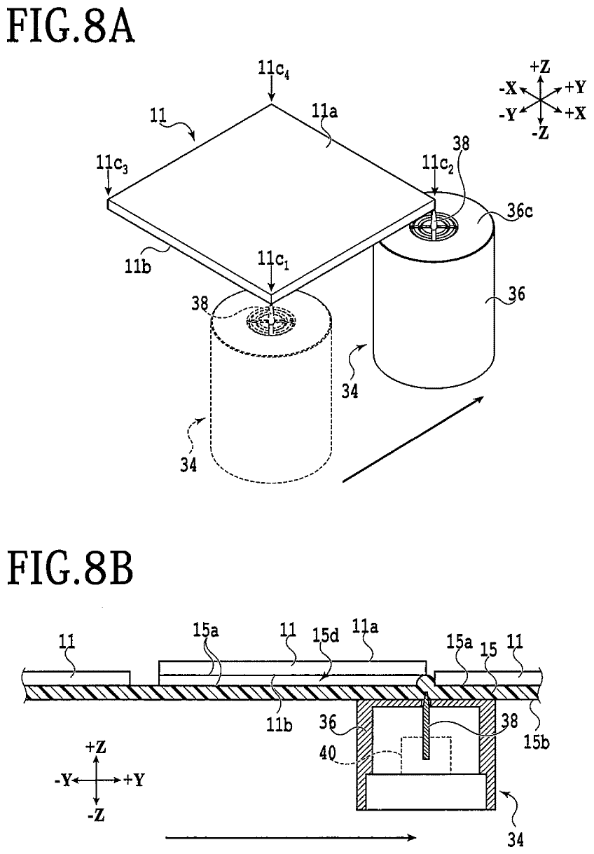

After the part of the chip 11 is peeled off from the sheet 15, while holding the other surface 15b of the sheet 15 on the holding surface 36c and pushing up the chip 11 with the pin 38 having the top portion 38a positioned at the protrusion position are maintained, in such a manner that the pin 38 is positioned at the second corner 11c₂ of the chip 11 (that is, the second position) different from the first corner 11c₁ in the XY plane, a relative position between the ejector mechanism 34 and the chip 11 is adjusted by the moving unit 33. Specifically, until the central region 38a₁ of the top portion 38a of the pin 38 is positioned immediately below the second corner 11c₂ of the chip 11, in such a manner that the pin 38 moves relative to the edge of the chip 11 along the edge of the chip 11, the moving unit 33 moves the chip unit 19 in the +Y direction. A relative movement speed of the pin 38 is in a range of 0.5 to 20 mm/s (for example, 1 mm/s). Hence, the peel-off region 15d (see FIG. 8B) in which the chip 11 is at least partly peeled off from the sheet 15 is enlarged (peel-off region enlargement step S50).

FIG. 8A is a perspective view depicting the manner in which the peel-off region 15d is enlarged, and FIG. 8B is partially cross-sectional side view of FIG. 8A. In the present embodiment, after the pin 38 is moved immediately below the second corner 11c₂, while holding the other surface 15b of the sheet 15 on the holding surface 36c and pushing up the chip 11 with the pin 38 having the top portion 38a positioned at the protrusion position are maintained, the moving unit 33 moves the pin 38 relative to the chip 11 in the XY plane, so that the peel-off region 15d is further enlarged.

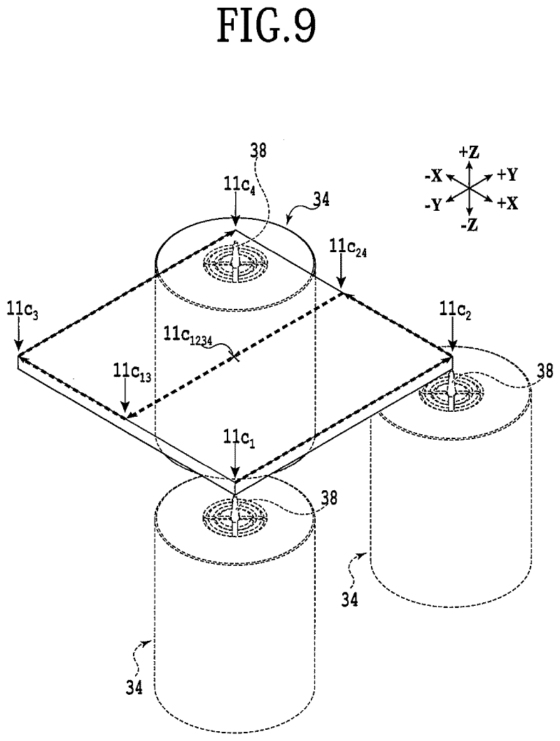

FIG. 9 is a perspective view depicting the manner in which the peel-off region 15d is further enlarged in the present embodiment. In FIG. 9, a path of the relative movement of the pin 38 is depicted with a dashed arrow, but what actually moves is the chip unit 19.

In the example depicted in FIG. 9, after the pin 38 is moved to the second corner 11c₂ in the XY plane, the moving direction of the pin 38 is changed by 90°. Then, the pin 38 is relatively moved in the X-axis direction along the edge of the chip 11 by the moving unit 33 to one point 11c₂₄ (for example, a middle point) between the second corner 11c₂ and the fourth corner 11c₄. Next, the moving direction of the pin 38 is changed by 90°, and in an opposite direction to the moving path between the first corner 11c₁ and the second corner 11c₂, the moving unit 33 causes the pin 38 to relatively move in the Y-axis direction so as to pass through the center 11c₁₂₃₄ of the back surface 11b of the chip 11 to the one point 11c₁₃ (for example, a middle point) between the first corner 11c₁ and the third corner 11c₃. Subsequently, with the moving direction of the pin 38 being changed by 90°, after the pin 38 is relatively moved in the X-axis direction along the edge of the chip 11 from the one point 11c₁₃ to the third corner 11c₃ by the moving unit 33, the pin 38 is relatively moved in the Y-axis direction along the edge of the chip 11 from the third corner 11c₃ to the fourth corner 11c₄ by the moving unit 33.

When the pin 38 reaches the fourth corner 11c₄ in the XY plane, the peel-off region enlargement step S50 is ended. Note that such relative movement of the pin 38 is made possible by the controller 110 monitoring information on the whole of the outer peripheral edge of the chip 11 or the coordinates of the four corners of the outer peripheral edge. In the present embodiment, the chip 11 and the pin 38 are moved relative to each other in such a manner that the pin 38 passes through the center 11c₁₂₃₄ of the back surface 11b and meanders relative to a straight line parallel to the X-axis direction, but the movement path of the pin 38 is not limited to the example depicted in FIG. 9. The path through which the pin 38 moves from the first corner 11c₁ and the fourth corner 11c₄ may also have various other options.

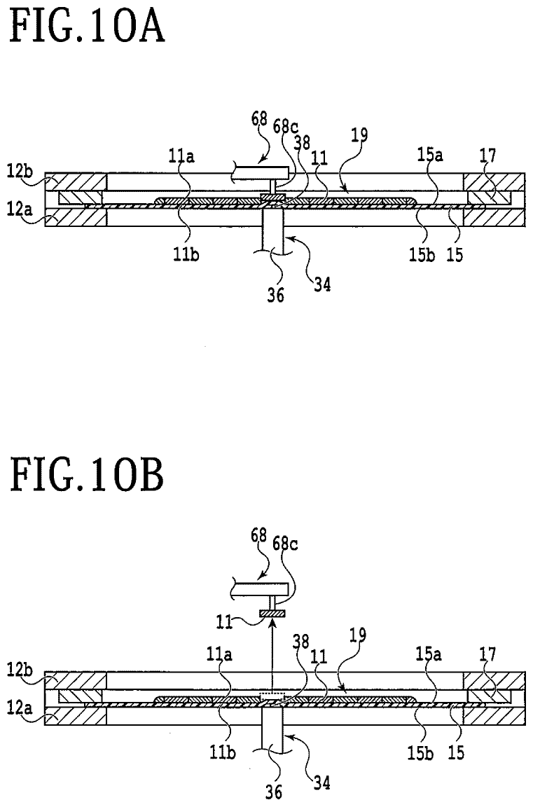

After the peel-off region enlargement step S50, in such a manner that the pin 38 is positioned at the center 11c₁₂₃₄ in the XY plane, the moving unit 33 adjusts the relative position between the pin 38 and the chip 11. Then, while the top portion 38a of the pin 38 pushes up the chip 11 through the sheet 15, the front surface 11a of the chip 11 is held under suction by the collet 68c (see FIG. 10A). FIG. 10A is a view depicting the manner in which the pin 38 pushes up the chip 11 while the collet 68c holds the chip 11 under suction.

Then, while the chip 11 holds the collet 68c under suction, the raising and lowering mechanism 64 moves the collet 68c upward, and the chip 11 is separated from the sheet 15 and picked up from the chip unit 19. FIG. 10B is a view depicting the manner in which the collet 68c picks up the chip 11.

In the present embodiment, in a case in which the protrusion amount of the pin 38 is increased, damage applied to the chip 11 when the chip 11 is picked up from the sheet 15 is reduced. That is, while enlarging the peel-off region 15d ensures reliable separation of the chip 11 and the sheet 15, a possibility in which the chip 11 is broken can be further reduced, compared to a case in which the protrusion amount of the pin 38 is increased. Further, in the present embodiment, the chip 11 experiences a physical impact in the Z-axis direction from being pushed up by the pin 38 only once, at the first corner 11c₁. The inventor of the present application has recognized that the yield of the chip 11 peeled off from the sheet 15 in the method according to the present embodiment is 99.9%.

In contrast, even if the pin 38 is moved as in the present embodiment, in a case in which such an operation that the top portion 38a of the pin 38 is positioned at the retracted position after the top portion 38a of the pin 38 is positioned at the protrusion position without keeping the state in which the top portion 38a of the pin 38 is positioned at the protrusion position and the top portion 38a thereof is then returned to the retracted position after the top portion 38a thereof is positioned at the protrusion position at a different position of the chip 11 in the XY plane is repeated, the chip 11 experiences an impact caused by the protrusion of the top portion 38a of the pin 38 every time. The inventor of the present application has recognized that, in a case in which the number of times at which the top portion 38a of the pin 38 pushes up increases and damage to the chip 11 thereby increases, the yield of the chip 11 peeled off from the sheet 15 remarkably lowers in this manner. For example, the inventor of the present application has recognized that the yield of the chip 11 positioned at the central portion of the radial direction of the semiconductor wafer 13 is 80% and the yield of the chip 11 positioned at the outer peripheral portion of the radial direction of the semiconductor wafer 13 is 0%.

As matter of course, while the pin 38 moves from the first corner 11c₁ to the second corner 11c₂, as described above, while holding the other surface 15b of the sheet 15 on the holding surface 36c and pushing up the pin 38 are maintained, only moving the pin 38 relative to the chip 11 sufficiently contributes to reduction in damage to the chip 11 applied when the chip 11 is picked up from the sheet 15.

After the chip 11 is picked up from the sheet 15, as depicted in FIG. 11, the arm 66 and the pickup unit 68 are moved. FIG. 11 is a view depicting the manner in which the pickup unit 68 moves the chip 11. Then, the mounted portion 68a of the pickup unit 68 is mounted to the mounting portion 72b of the moving mechanism 72.

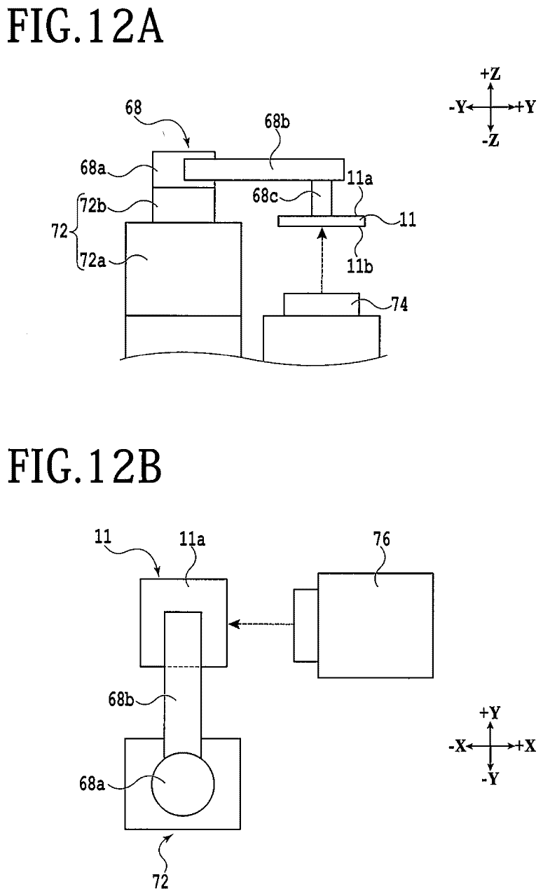

Next, the moving mechanism 72 on the vibration isolation table 70, the drive source in the support portion 68b, and the like adjust the position of the chip 11 held under suction by the collet 68c, and as depicted in FIG. 12A, the second camera unit 74 images the non-suction surface (that is, the back surface 11b) of the chip 11, and images the side surface of the chip 11 with the third camera unit 76 as depicted in FIG. 12B.

In a case of imaging the side surface of the chip 11 with the third camera unit 76, one side surface where cracking in the following destruction test occurs may be imaged, two side surfaces where cracking occurs may be imaged, and four side surfaces may be imaged. In addition, either the non-suction surface or the side surface of the chip 11 may be imaged first or at the same time.

FIG. 12A is a view depicting the manner in which the non-suction surface of the chip 11 is imaged, and FIG. 12B is a view depicting the manner in which the side surface of the chip 11 is imaged. In a case of imaging the non-suction surface and the side surface of the chip 11, it is preferable that, by use of the moving mechanism 72, the drive source in the support portion 68b, and the like, an imaging region be moved and a plurality of images form images of the non-suction surface and the side surface. This allows the state of the chip 11 before the destruction test to be more accurately monitored.

After the non-suction surface and the side surface of the chip 11 are imaged, the destruction test for the chip 11 is performed by use of the test unit 80. For the test, first, contact of the mounted portion 68a and the mounting portion 72b is released, and the mounted portion 68a is mounted to the mounting portion 66a. Then, the pickup unit 68 is moved to the test unit 80 by the raising and lowering mechanism 64, the Y-axis direction moving mechanism 54, and the like, and as depicted in FIG. 13, the chip 11 is placed on the pair of receiving portions 84a. At this time, the back surface 11b of the chip 11 comes into contact with the pair of receiving portions 84a, and the front surface 11a thereof is exposed upward.

FIG. 13 is a view depicting the manner in which the chip 11 is supported by the pair of support portions 84. After the chip 11 is supported by the pair of support portions 84, the Z-axis direction moving mechanism 98 is operated to cause the indenter 88 to gradually be moved closer to the chip 11. After the distal end portion 88a of the indenter 88 comes into contact with the front surface 11a of the chip 11, when the chip 11 is pressed by the indenter 88, the chip 11 is broken as depicted in FIG. 14. FIG. 14 is a view depicting the manner in which the load applied to the indenter 88 when the chip 11 is pressed by the indenter 88 and the chip 11 is broken is measured by the load measuring unit 92. The load applied to the chip 11 is monitored by the controller 110 through the load measuring unit 92 in real time.

In the present embodiment, since the chip 11 is picked up in the pickup method described above, the damage applied to the chip 11 when the chip 11 is picked up from the sheet 15 can be reduced. Accordingly, it is possible to more accurately measure the original bending strength of the chip 11.

Besides, structures, methods, and the like according to the above-described embodiment can be carried out with appropriate changes without departing from the scope of the object of the present invention. For example, the relative movement of the chip 11 and the pin 38 in S50 of FIG. 4 is not limited to movement in the direction completely parallel to the Y-axis direction or the X-axis direction. As long as the top portion 38a of the pin 38 can be pushed up to the sheet 15 while the other surface 15b of the sheet 15 is held under suction on the holding surface 36c, the chip 11 and the pin 38 may be moved relative to each other in such a manner as to be inclined to the Y-axis direction in a YZ plane, and may be moved relative to each other in such a manner as to be inclined to the X-axis direction in the XZ plane.

In the embodiment described above, although the first corner 11c₁ is set as the first position, the first position may be the second corner 11c₂, the third corner 11c₃, the fourth corner 11c₄, the one point 11c₁₃, the one point 11c₂₄, and the like. According to the change of the first position, the second position may also be changed as needed. For example, it may also be possible to set the one point 11c₁₃ as the first position and set the one point 11c₂₄ as the second position.

In addition, according to the embodiment described above, after the pickup unit 68 places the chip 11 on the pair of support portions 84, the chip 11 supported by the pair of support portions 84 is broken by the indenter 88. However, by pressing the chip 11 held under suction by the pickup unit 68 to the pressing unit 86 provided in such a manner as to protrude from the one surface 4a of the base 4, the chip 11 may be broken.

Note that, in a case in which the chip 11 held under suction by the pickup unit 68 is pressed to the indenter 88, the pickup unit 68 may hold under suction not the central portion of the front surface 11a of the chip 11, but the pair of end portions or the four corners of the front surface 11a of the chip 11.

Meanwhile, in the test apparatus 2 according to the embodiment described above, the −Z direction is a vertical direction. However, the vertical direction is not limited to this example, and the +Z direction may be the vertical direction, or the Z-axis direction may be inclined to the vertical direction.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A pickup method of picking up a chip fixed to one surface of a sheet from the sheet, the method comprising:
adjusting a relative position of an ejector mechanism and the chip, the ejector mechanism including a housing having a holding surface at a distal end portion thereof, the holding surface capable of applying a holding force to another surface of the sheet, and a pin having a movable tip end portion, the tip end portion of the pin being movable between a protrusion position at which the tip end portion of the pin moves upward from the holding surface and a retracted position at which the tip end portion of the pin does not move upward from the holding surface and is retracted in the housing, in a predetermined plane perpendicular to a direction in which the pin moves between the protrusion position and the retracted position, in such a manner that the pin is positioned at a first position of the chip which is movable upward to push up the chip through the sheet from the other surface of the sheet at the protrusion position;
applying the holding force to the holding surface with the tip end portion of the pin being positioned in the retracted position and holding the other surface of the sheet on the holding surface;
after the pin is positioned at the first position in the predetermined plane and the other surface of the sheet is held on the holding surface, moving the tip end portion of the pin to the protrusion position while holding the other surface of the sheet on the holding surface is maintained, and pushing up the chip with the pin, thereby peeling off part of the chip from the sheet;
after the part of the chip is peeled off from the sheet, adjusting the relative position between the ejector mechanism and the chip, in such a manner that the pin is positioned at a second position of the chip different from the first position in the predetermined plane while holding the other surface of the sheet on the holding surface and the pushing up the chip with the pin having the tip end portion positioned at the protrusion position are maintained, thereby enlarging a peel-off region where the chip is at least partially peeled off from the sheet; and,
after the pin is moved to the second position, holding the chip with a collet and separating the chip from the sheet, and picking up the chip.

2. A test method of measuring a load applied when a chip fixed to one surface of a sheet is broken after the chip is picked up from the sheet, the method comprising:
adjusting a relative position of an ejector mechanism and the chip, the ejector mechanism including a housing having a holding surface at a distal end portion thereof, the holding surface capable of applying a holding force to another surface of the sheet, and a pin having a movable tip end portion, the tip end portion of the pin being movable between a protrusion position at which the tip end portion of the pin moves upward from the holding surface and a retracted position at which the tip end portion of the pin does not move upward from the holding surface and is retracted in the housing, in a predetermined plane perpendicular to a direction in which the pin moves between the protrusion position and the retracted position, in such a manner that the pin is positioned at a first position of the chip which is movable upward to push up the chip through the sheet from the other surface of the sheet at the protrusion position;
applying the holding force to the holding surface with the tip end portion of the pin being positioned at the retracted position and holding the other surface of the sheet on the holding surface;
after the pin is positioned at the first position in the predetermined plane and the other surface of the sheet is held on the holding surface, moving the tip end portion of the pin to the protrusion position while holding the other surface of the sheet on the holding surface is maintained, and pushing up the chip with the pin, thereby peeling off part of the chip from the sheet;
after the part of the chip is peeled off from the sheet, adjusting the relative position between the ejector mechanism and the chip, in such a manner that the pin is positioned at a second position of the chip different from the first position in the predetermined plane while holding the other surface of the sheet on the holding surface and the pushing up the chip with the pin having the tip end portion positioned at the protrusion position are maintained, thereby enlarging a peel-off region where the chip is at least partially peeled off from the sheet;
after the pin is moved to the second position, holding the chip with a collet and separating the chip from the sheet, and picking up the chip;
after the chip is picked up from the sheet, pressing the chip with an indenter to break the chip; and
measuring the load applied to the indenter when the chip is broken.

3. A pickup device which picks up a chip fixed to one surface of a sheet, comprising:
a sheet holding unit configured to hold the sheet;
an ejector mechanism including a housing having a holding surface at a distal end portion thereof, the holding surface capable of applying a holding force to another surface of the sheet held by the sheet holding unit, and a pin having a movable tip end portion, the tip end portion of the pin being movable between a protrusion position at which the tip end portion of the pin moves upward from the holding surface and a retracted position at which the tip end portion of the pin does not move upward from the holding surface and is retracted in the housing;
a moving unit which moves the ejector mechanism and the sheet held by the sheet holding unit relative to each other;
a pickup unit having a collet to hold the chip with the collet and separate the chip from the sheet; and
a controller which has a processor and a memory, and which controls the sheet holding unit, the ejector mechanism, the moving unit, and the pickup unit,
wherein, when the collet picks up the chip from the sheet, the controller performs
adjusting, by the moving unit, a relative position of the ejector mechanism and the chip, in a predetermined plane perpendicular to a direction in which the pin moves between the protrusion position and the retracted position, in such a manner that the pin is positioned at a first position of the chip which is movable upward to push up the chip through the sheet from the other surface of the sheet at the protrusion position,
applying the holding force to the holding surface with the tip end portion of the pin being positioned in the retracted position and holding the other surface of the sheet on the holding surface,
after the pin is positioned at the first position in the predetermined plane and the other surface of the sheet is held on the holding surface, moving the tip end portion of the pin to the protrusion position while holding the other surface of the sheet on the holding surface is maintained, and pushing up the chip with the pin, thereby peeling off part of the chip from the sheet,
after the part of the chip is peeled off from the sheet, adjusting, by the moving unit, the relative position between the ejector mechanism and the chip, in such a manner that the pin is positioned at a second position of the chip different from the first position in the predetermined plane while holding the other surface of the sheet on the holding surface and the pushing up the chip with the pin having the tip end portion positioned at the protrusion position are maintained, thereby enlarging a peel-off region where the chip is at least partially peeled off from the sheet, and,
after the pin is moved to the second position, holding the chip with the collet of the pickup unit and separating the chip from the sheet, and picking up the chip.

4. A test apparatus which measures a load applied when a chip fixed to one surface of a sheet is broken after the chip is picked up from the sheet, comprising:
a sheet holding unit which holds the sheet;
an ejector mechanism including a housing having a holding surface at a distal end portion thereof, the holding surface capable of applying a holding force to another surface of the sheet held by the sheet holding unit, and a pin having a movable tip end portion, the tip end portion of the pin being movable between a protrusion position at which the tip end portion of the pin moves upward from the holding surface and a retracted position at which the tip end portion of the pin does not move upward from the holding surface and is retracted in the housing;
a moving unit which moves the ejector mechanism and the sheet held by the sheet holding unit relative to each other;
a pickup unit having a collet to hold the chip with the collet and separate the chip from the sheet;
an indenter which breaks the chip picked up from the sheet;
a load measuring unit which measures the load applied to the indenter when the indenter breaks the chip; and
a controller which has a processor and a memory, which controls the sheet holding unit, the ejector mechanism, the moving unit, the pickup unit, and the indenter, and which receives output from the load measuring unit,
wherein, when the collet picks up the chip from the sheet, the controller performs
adjusting, by the moving unit, a relative position of the ejector mechanism and the chip, in a predetermined plane perpendicular to a direction in which the pin moves between the protrusion position and the retracted position, in such a manner that the pin is positioned at a first position of the chip which is movable upward to push up the chip through the sheet from the other surface of the sheet at the protrusion position,
applying the holding force to the holding surface with the tip end portion of the pin being positioned at the retracted position and holding the other surface of the sheet on the holding surface,
after the pin is positioned at the first position in the predetermined plane and the other surface of the sheet is held on the holding surface, moving the tip end portion of the pin to the protrusion position while holding the other surface of the sheet on the holding surface is maintained, and pushing up the chip with the pin, thereby peeling off part of the chip from the sheet,
after the part of the chip is peeled off from the sheet, adjusting, by the moving unit, the relative position between the ejector mechanism and the chip, in such a manner that the pin is positioned at a second position of the chip different from the first position while holding the other surface of the sheet on the holding surface and the pushing up the chip with the pin having the tip end portion positioned at the protrusion position are maintained in the predetermined plane, thereby enlarging a peel-off region where the chip is at least partially peeled off from the sheet, and,
after the pin is moved to the second position, holding the chip with the collet of the pickup unit and separating the chip from the sheet, and picking up the chip, and,
after the collet picks up the chip from the sheet, the controller performs
pressing the chip with the indenter to break the chip, and,
when the chip is broken, causing the load measuring unit to measure the load applied to the indenter.
